(19) United States
(12) Patent Application Publication
(10) Pub. No.: US 2024/0097417 A1
(43) Pub. Date: Mar. 21, 2024

(54) ELECTRICAL JUNCTION BOX

(71) Applicant: Sumitomo Wiring Systems, Ltd., Yokkaichi-shi, Mie (JP)

(72) Inventors: Maiko ISSHIKI, Yokkaichi-shi, Mie (JP); Hideki GOTO, Yokkaichi-shi, Mie (JP)

(21) Appl. No.: 18/264,893

(22) PCT Filed: Jan. 26, 2022
(86) PCT No.: PCT/JP2022/002750

§ 371 Date: Aug. 9, 2023

(30) Foreign Application Priority Data
Feb. 12, 2021 (JP) 2021-021052

(51) Int. Cl. H02G 3/16; B60R 16/023; F16B 43/00

(52) U.S. Cl. CPC H02G 3/16; B60R 16/0238; F16B 43/00

(57) ABSTRACT

Provided is an electrical junction box that can efficiently reduce, with a simple configuration, the heat of a busbar, and can be manufactured at low cost. An electrical junction box for vehicles that is provided with a busbar fixed using a bolt and a nut includes a washer that is interposed between the bolt and the busbar, and is made of the same material as that of the busbar.

### CROSS-REFERENCE TO RELATED APPLICATIONS

This application is the U.S. national stage of PCT/JP2022/002750 filed on Jan. 26, 2022, which claims priority of Japanese Patent Application No. JP 2021-021052 filed on Feb. 12, 2021, the contents of which are incorporated herein.

### TECHNICAL FIELD

The present disclosure relates to an electrical junction box for vehicles that is provided with a busbar.

### BACKGROUND

Conventionally, electrical junction boxes with a circuit that uses a busbar to conduct a relatively large current are mounted in vehicles. Recently, with an extension of vehicle functions, a current flowing through a busbar tends to increase.

JP 2014-79093A discloses a power supply apparatus that is provided with a relay including an openable and closable contact, and an exciting coil for switching the contact between an open state and a closed state, wherein the busbar can serve as a current path and as a heat dissipation path by electrically connecting the contact of the relay to the busbar, and providing a heat dissipation mechanism in the busbar.

Meanwhile, an increase in current flowing through a busbar leads to an increase in heat generation amount caused by an electrical resistance. To address the problem and enhance the heat resistance performance of the busbar, typically, a technique of using a wider or thicker busbar, or a technique of using another member for increasing so-called thermal mass (drawing and storing heat) is employed.

However, mass production of wide busbars or thick busbars is not easy because they are difficult to be processed, thus resulting in a high process cost and a low yield ratio. Also, if another member for increasing thermal mass is used, there are problems that the configuration is complicated due to an increased number of components, and the number of assembling steps also increases.

However, in the power supply apparatus according to JP 2014-79093A, such problems are not taken into consideration, and cannot be solved. Therefore, it is an object of the present invention to provide an electrical junction box that can reduce the heat of a busbar with a simple configuration, and can be manufactured at low cost.

### SUMMARY

An electrical junction box according to the present disclosure is directed to an electrical junction box for vehicles that is provided with a busbar fixed using a bolt and a nut, the electrical junction box including a washer that is interposed between the bolt and the busbar, and is made of the same material as that of the busbar.

### Effects

According to the present disclosure, it is possible to provide an electrical junction box that can efficiently reduce the heat of a busbar with a simple configuration, and can be manufactured at low cost.

### BRIEF DESCRIPTION OF DRAWINGS

FIG. 1 is a plane view illustrating an electrical junction box according to Embodiment 1.

FIG. 2 is a side view of the electrical junction box according to Embodiment 1.

FIG. 3 is a bottom view illustrating the electrical junction box according to Embodiment 1 in a state in which a lower case is removed.

FIG. 4 is a perspective view illustrating an example of a busbar to be attached to the electrical junction box according to Embodiment 1.

FIG. 5 is a perspective view illustrating a state in which the busbar is attached to a seat.

FIG. 6 is an exemplified diagram illustrating a modification of the electrical junction box according to Embodiment 1.

FIG. 7 is a perspective view illustrating the electrical junction box according to Embodiment 2 in a state in which the busbar is attached to the seat.

FIG. 8 is a perspective view illustrating the electrical junction box according to Embodiment 3 in a state in which the busbar is attached to the seat.

FIG. 9 is a perspective view illustrating the electrical junction box according to Embodiment 4 in a state in which the busbar is attached to the seat.

### DETAILED DESCRIPTION OF PREFERRED EMBODIMENTS

First, embodiments of the present disclosure will be listed and described. Also, at least some of the embodiments described below may be combined with each other as appropriate.

An electrical junction box according to an embodiment of the present disclosure is directed to an electrical junction box for vehicles that is provided with a busbar fixed using a bolt and a nut, the electrical junction box including a washer that is interposed between the bolt and the busbar, and is made of the same material as that of the busbar.

According to the present embodiment, since the washer interposed between the bolt and the busbar is made of the same material as that of the busbar, the washer can rapidly absorb heat generated by the busbar.

In the electrical junction box according to the embodiment of the present disclosure, the washer has a thickness that is at least 1.5 times as large as a thickness of the busbar.

According to the present embodiment, since the thickness of the washer is at least 1.5 times as large as the thickness of the busbar, the washer can absorb and store a large amount of heat generated from the busbar.

In the electrical junction box according to the embodiment of the present disclosure, the washer is made of copper.

According to the present embodiment, since the washer is made of the same material as that of the busbar, the washer can rapidly absorb and store heat generated from the busbar.

In the electrical junction box according to the embodiment of the present disclosure, the washer has an uneven surface.

According to the present embodiment, since the washer has an uneven surface, it is possible to ensure a larger surface area. Therefore, when the heat generated from the busbar and absorbed by the washer is dissipated via the surface of the washer, the heat dissipation efficiency can be improved.

In the electrical junction box according to the embodiment of the present disclosure, the bolt has an uneven surface.

According to the present embodiment, since the bolt has an uneven surface, it is possible to ensure a larger surface area. Therefore, when the heat generated from the busbar and absorbed by the bolt is dissipated via the surface of the bolt, the heat dissipation efficiency can be improved.

In the electrical junction box according to the embodiment of the present disclosure, the nut has an uneven surface.

According to the present embodiment, since the nut has an uneven surface, it is possible to ensure a larger surface area. Therefore, when the heat generated from the busbar and absorbed by the nut is dissipated via the surface of the nut, the heat dissipation efficiency can be improved.

### DETAILS OF EMBODIMENTS OF PRESENT DISCLOSURE

Hereinafter, the electrical junction box according to embodiments of the present disclosure is described with reference to the drawings. Note that the present disclosure is not limited to these examples but is defined by the claims, and all modifications within the meaning and scope equivalent to the claims are intended to be included.

### Embodiment 1

The following describes the present embodiment taking an electrical junction box for vehicles to which a busbar is mounted, as an example.

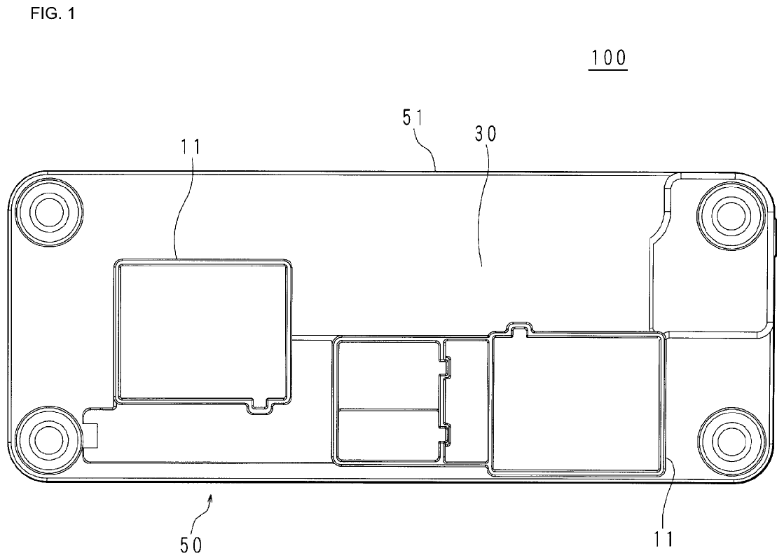

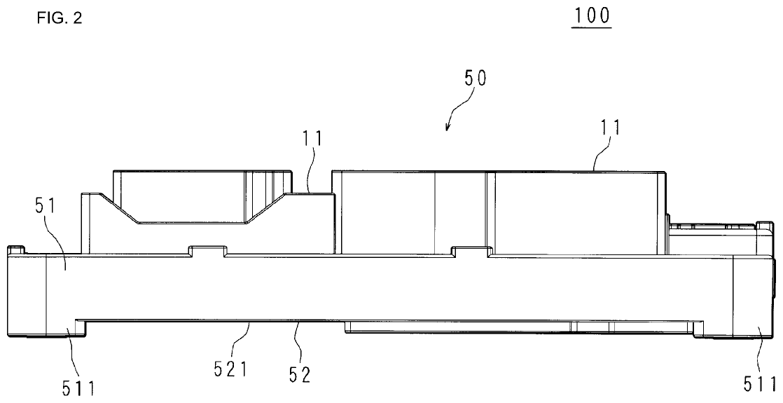

FIG. 1 is a plane view of an electrical junction box 100 according to Embodiment 1, and FIG. 2 is a side view of the electrical junction box 100 according to Embodiment 1.

The electrical junction box 100 is attached to an outer side of a battery pack of an electric vehicle (EV), for example. The electrical junction box 100 includes a housing 50 in which electric components such as relays are mounted, for example.

The housing 50 is made of, for example, a resin, and is constituted by a lower case 52 and an upper case 51 that covers the lower case 52. The housing 50 is attached to the battery pack in a manner such that a bottom plate 521 of the lower case 52 faces the battery pack of the EV. At this time, the bottom plate 521 of the lower case 52 faces an outer surface of the battery pack.

Hereinafter, for ease of description, with respect to a direction in which the electrical junction box 100 faces the battery pack, the side on which the electrical junction box 100 is located is defined as an upper side, and the side on which the battery pack is located is defined as a lower side.

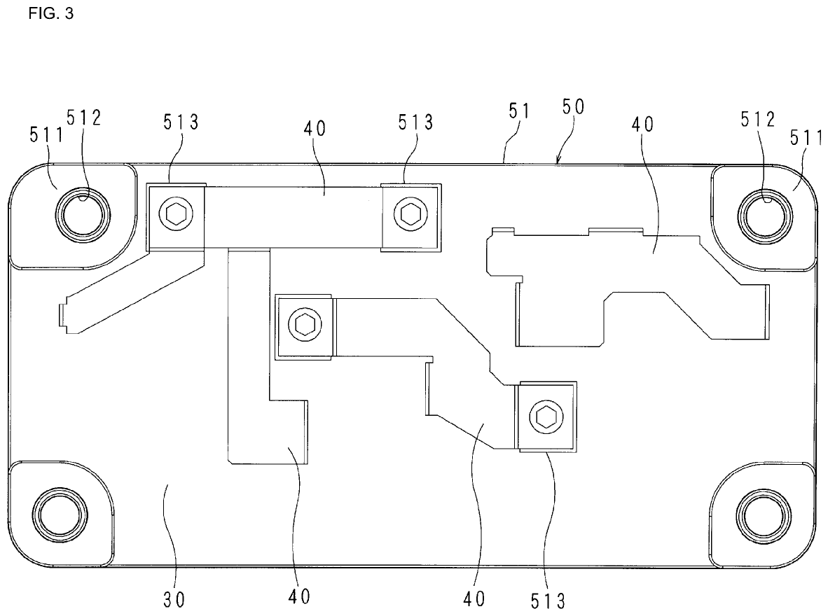

FIG. 3 is a bottom view illustrating the electrical junction box 100 according to Embodiment 1 in a state in which the lower case 52 is removed. The upper case 51 is box-shaped with one side open, and busbars 40, circuit elements and the like are attached to the inside of the upper case 51.

The upper case 51 has a ceiling plate 30 that faces the bottom plate 521 of the lower case 52. Mounting parts 11 for mounting an electric component such as a relay are provided at two positions on an outer surface of the ceiling plate 30. A plurality of connecting parts (not shown) for making a connection to an external fuse, connector or the like are also provided on the ceiling plate 30.

The upper case 51 has, at four positions, leg portions 511 in the shape of a bottomed tube. More specifically, each leg portion 511 protrudes in a direction orthogonal to the ceiling plate 30 at a position in or near a corner of the ceiling plate at which the leg portion 511 does not interfere with the corresponding mounting part 11 and connecting part. A through hole 512 is formed in the bottom of each leg portion 511. For example, by inserting a screw into the through hole 512 in the leg portion 511 and screwing the screw into a screw hole in the battery pack of the EV, it is possible to attach the housing 50 (electrical junction box 100) to the battery pack.

The ceiling plate 30 includes ribs (not shown) at a plurality of positions on an inner surface thereof, and a plurality of seats 513 for mounting busbars 40, circuit elements and the like are provided. The busbars 40, circuit elements and the like are attached to the corresponding seats 513.

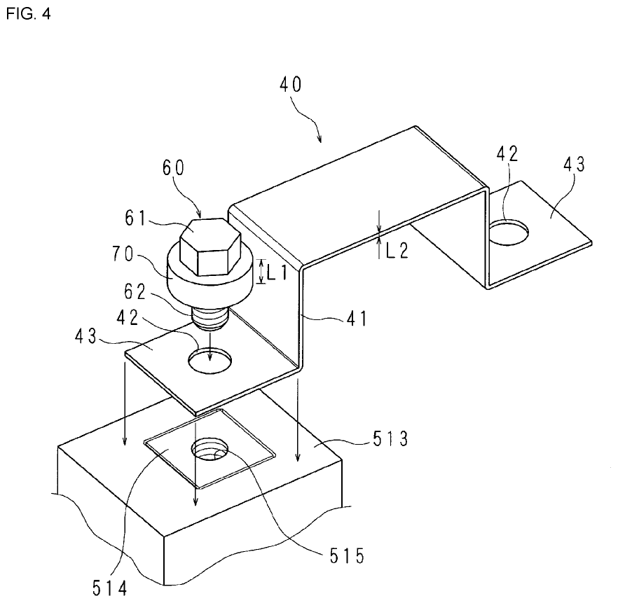

FIG. 4 is a perspective view illustrating an example of a busbar 40 to be attached to the electrical junction box 100 according to Embodiment 1. FIG. 4 shows, for convenience, a state in which the busbar 40 is removed from the seat 513.

Although illustration is omitted, at least one end of the busbar 40 is electrically connected to the connecting part or the mounting part 11, and a relatively high voltage (for example, 300 V or more) is applied to the busbar 40.

The busbar 40 is made of a thin plate material of a conductive metal (for example, copper). For example, in Embodiment 1, the thickness of the busbar 40 is 1.5 mm. The busbar 40 is obtained by bending a strip-shaped thin plate at a plurality of positions, and is constituted by a central portion 41 in the shape of an inverted U shape, and rectangular flat guards 43 extending from two ends of the central portion 41. The central portion 41 and the flat guards 43 are formed as one piece. Each of the flat guards 43 has a fixation hole 42 for fixing the busbar 40 to the seat 513 of the upper case 51. The fixation hole 42 is a through hole passing through the corresponding flat guard 43 in the thickness direction.

A square nut 514 is embedded in the seat 513. As a result of a bolt 60 being inserted into the fixation hole 42 in the busbar 40, and being screwed into a screw hole 515 in the square nut 514 of the seat 513, the busbar 40 is fixed to the seat 513.

At this time, a washer 70 is interposed between the bolt 60 and the flat guard 43 of the busbar 40. That is to say, the bolt 60 has a hexagonal columnar retaining head 61 at one end thereof, and the washer 70 is interposed between the retaining head 61 and the flat guard 43.

The washer 70 is tubular, and has an inner diameter that is smaller than the diameter (dimension between opposing edges) of the retaining head 61 of the bolt 60 and is larger than the diameter of a columnar thread portion 62 of the bolt 60. Also, a dimension (hereinafter, referred to as “thickness”) L1 of the washer 70 in a direction along the axis thereof is at least 1.5 times as large as a thickness L2 of the busbar 40.

Furthermore, the washer 70 is made of the same material as that of the busbar 40. That is to say, in the present embodiment, the busbar 40 is made of copper, and thus the washer 70 is also made of copper that is the same material as that of the busbar 40.

In the electrical junction box 100 according to Embodiment 1, the busbar can be subjected to batch process such that a thin plate-shaped copper material is pressed using a progressive die with bending positions offset by an amount corresponding to the thickness of the plate material. By performing punching and bridge cut on the thin plate-shaped copper material using such a progressive die, and bending the thin plate-shaped copper material, the busbar 40 is obtained.

Meanwhile, due to diversification of functions of vehicles, the number of electric components mounted in a vehicle is increasing, and thus currents flowing through the electrical junction box (busbar) are also increasing. Such an increase in current leads to an increase in heat generation amount in a busbar caused by an electrical resistance. To address the problem and enhance the heat resistance performance of the busbar, a technique of using a wider or thicker busbar, or technique of using another member for increasing so-called thermal mass is employed. In this context, “thermal mass” is meant by drawing and storing heat.

However, mass production of wide busbars or thick busbars is not easy because, for example, press work using a progressive die cannot be used, thus resulting in a high process cost and a low yield ratio. Also, if another member for increasing thermal mass is used, this will lead to an increase in the number of components, and also to an increase in the number of assembling steps, resulting in a high manufacturing cost.

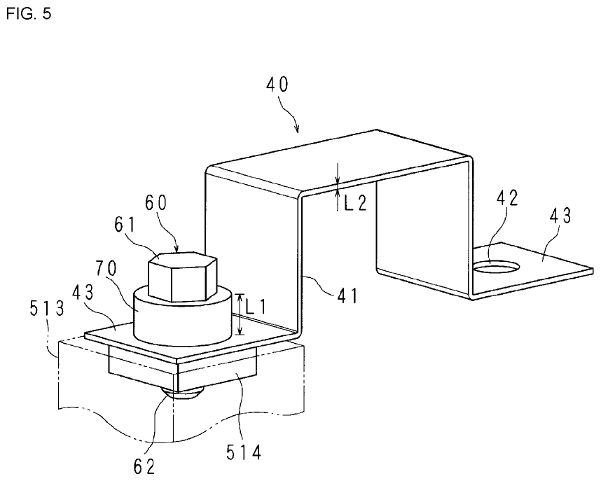

In contrast, the electrical junction box 100 according to Embodiment 1 is provided with the washer 70, and thus can solve the above-described problem. Detailed description will be given below with reference to FIG. 5. FIG. 5 is a perspective view showing a state in which the busbar 40 is attached to the seat 513. In FIG. 5, for ease of description, the seat 513 is shown in a dashed-two dotted line.

As shown in FIG. 5, in the electrical junction box 100 according to Embodiment 1, the washer 70 is interposed between the busbar 40 and the retaining head 61 of the bolt 60, and the busbar 40 is in contact with the washer 70. Furthermore, as described above, the washer 70 is made of copper that is the same as that of the busbar 40, and the thickness L1 of the washer 70 is at least 1.5 times as large as the thickness L2 of the busbar 40 (see FIG. 4).

Preferably, the thickness L1 of the washer 70 is 2 to 5 times as large as the thickness L2 of the busbar 40. This is because if the thickness L1 of the washer 70 is too large, this may interfere assembling work and increase the manufacturing cost.

That is to say, since the washer 70 is made of the same material as that of the busbar 40, the heat generated in the busbar 40 due to current conduction rapidly propagates to and is absorbed by the washer 70. Also, since the thickness L1 of the washer 70 is at least 1.5 times as large as the thickness L2 of the busbar 40, the washer 70 can store a significant amount of heat of the busbar 40. The heat absorbed by the washer 70 is dissipated with air cooling via the surface of the washer 70.

Note that part of the heat absorbed by the washer 70 is also dissipated via the bolt 60 and the square nut 514 that are in contact with the washer 70.

With this, in the electrical junction box 100 according to Embodiment 1, it is neither necessary to increase the width or thickness of the busbar 40 in order to endure and dissipate the heat generated due to current conduction, nor to provide any other component for increasing thermal mass. Therefore, it is possible to reduce and dissipate the heat generated in the busbar 40 with a simple configuration, while suppressing the dimension of the busbar 40.

Also, since the dimension of the busbar 40 can be suppressed and press work using a progressive die can be used, it is possible to achieve mass production and suppress the process cost, increasing the yield ratio. Also, since no other component for increasing thermal mass is needed, and an increase in the number of components is prevented, it is possible to suppress the manufacturing cost of the electrical junction box 100.

Although a configuration in which the thickness L1 of the washer 70 is at least 1.5 times as large as the thickness L2 of the busbar 40 has been described as an example, the present disclosure is not limited to this. For example, a configuration is also possible in which the outer diameter of the washer 70 is increased to the extent that it does not protrude from the flat guard 43.

Furthermore, although a case where only one of the flat guards 43 of the busbar 40 is attached to the seat 513 using the washer 70 has been described as an example, the present disclosure is not limited to this. A configuration is also possible in which both the flat guards 43 of the busbar 40 are respectively attached to the seats 513 using the washers 70.

Moreover, although a case where the electrical junction box 100 according to Embodiment 1 uses the square nut 514 has been described as an example, the present disclosure is not limited to this, and for example, a hexagonal nut, a butterfly nut or the like may also be used.

Note that, although a configuration in which the washer 70, which is greater than a normal washer, is used to draw and store heat from the busbar 40 has been described as an example, the present disclosure is not limited to this. For example, another larger component may also be used. The following will describe, as an example, a case where a large nut is used.

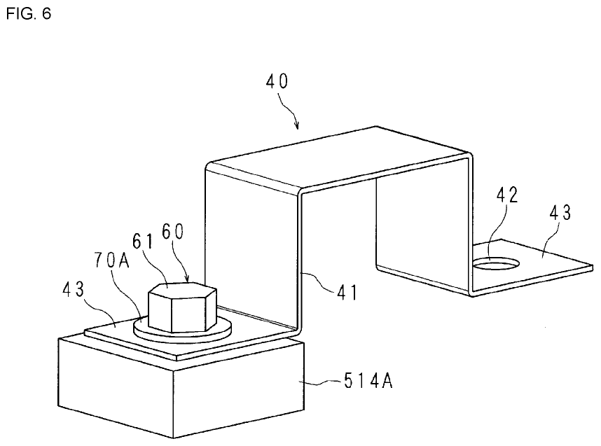

FIG. 6 is an exemplified diagram illustrating a modification of the electrical junction box 100 according to Embodiment 1. FIG. 6 shows, as an example, the busbar 40 in a state of being attached, and illustration of the seat 513 is omitted for ease of description.

As a result of the bolt 60 being inserted into the fixation hole 42 (see in FIG. 4) in the busbar 40, and being screwed with a square nut 514A, the busbar 40 (flat guard 43) is fixed to the seat 513. FIG. 6 shows a case where the bolt 60 is inserted through only one of the flat guards 43 of the busbar 40, and is screwed with the square nut 514A.

Also, a washer 70A is interposed between the hexagonal retaining head 61 of the bolt 60 and the flat guard 43. In the electrical junction box 100 according to the modification, the washer 70A is a normal washer, has the shape of a ring whose thickness is substantially equal to the thickness of the busbar 40, and is made of the same material as that of the busbar 40.

On the other hand, the electrical junction box 100 according to the modification includes, as shown in FIG. 6, the square nut 514A in a hexahedron shape, which is larger than a normal nut, and the face of the square nut 514A that is in contact with the flat guard 43 is larger than the main face of the flat guard 43.

Since the square nut 514A is in contact with the flat guard 43, the square nut 514A can absorb and store a large amount of heat generated in the busbar 40 due to current conduction. The heat absorbed by the square nut 514A is dissipated with air cooling via the surface of the square nut 514A.

As described above, the square nut 514A of the electrical junction box 100 according to the modification has a volume and a surface area that are larger than those of a normal washer. Accordingly, the square nut 514A can store a significant amount of heat from the busbar 40 and can dissipate the heat with air cooling via its surface more rapidly.

In the above-described example, although a configuration has been described in which instead of the washer 70, the size of the square nut 514 is increased in order that the heat generated by the busbar 40 is drawn and stored, the present disclosure is not limited to this, and the size of the retaining head 61 of the bolt 60 may also be increased instead.

### Embodiment 2

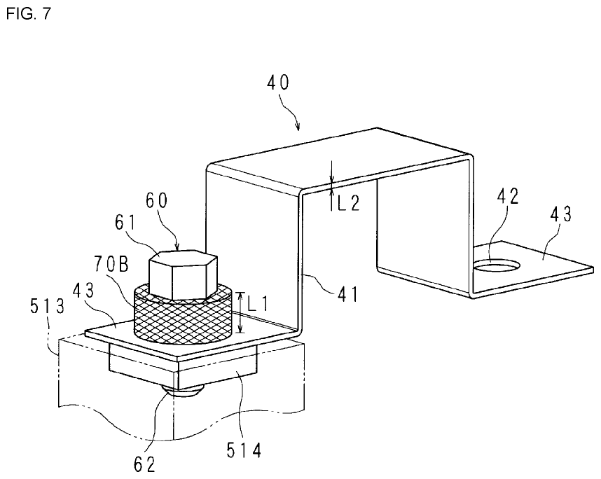

FIG. 7 is a perspective view illustrating the electrical junction box 100 according to Embodiment 2 in a state in which the busbar 40 is attached to the seat 513. In FIG. 7, for ease of description, the seat 513 is shown in dashed-two dotted lines.

In the electrical junction box 100 according to Embodiment 2, as a result of the bolt 60 being inserted into the fixation hole 42 (see in FIG. 4) in the busbar 40, and being screwed with the square nut 514 of the seat 513, the busbar 40 (flat guard 43) is fixed to the seat 513. FIG. 7 shows a case where only one of the flat guards 43 of the busbar 40 is attached to the seat 513.

Also, a washer 70B is interposed between the bolt 60 and the flat guard 43 of the busbar 40. The washer 70B is interposed between the hexagonal retaining head 61 of the bolt 60 and the flat guard 43.

The washer 70B is tubular, and has an inner diameter that is smaller than the diameter of the retaining head 61 of the bolt 60 and is larger than the diameter of the columnar thread portion 62. Also, the thickness L1 of the washer 70B is at least 1.5 times as large as a thickness L2 of the busbar 40. Furthermore, the washer 70B is made of the same material as that of the busbar 40.

Furthermore, in the electrical junction box 100 according to Embodiment 2, knurling is performed on the surface of the washer 70B and the surface of the washer 70B is uneven.

As described above, in the electrical junction box 100 according to Embodiment 2, since the washer 70B is made of the same material as that of the busbar 40, the heat generated in the busbar 40 due to current conduction rapidly propagates to and is absorbed by the washer 70B. Also, since the thickness L1 of the washer 70B is at least 1.5 times as large as the thickness L2 of the busbar 40, the washer 70B can store a significant amount of heat of the busbar 40. The heat absorbed by the washer 70B is dissipated with air cooling via the surface of the washer 70B.

Also, in the electrical junction box 100 according to Embodiment 2, since the surface of the washer 70B is uneven, a large specific surface area of the washer 70B is ensured, and the washer 70B has a larger area that is in contact with air. Accordingly, the washer 70B can perform air cooling or dissipate the stored heat more efficiently

With this, in the electrical junction box 100 according to Embodiment 2, it is not necessary to increase the dimension of the busbar 40 in order to endure and dissipate the heat generated due to current conduction, making it possible to suppress the dimension of the busbar 40 to the extent that press work using a progressive die is possible. This enables to achieve mass production and suppress the process cost, increasing the yield ratio. Also, no other component for increasing thermal mass is needed, and it is thus possible to reduce the number of components, and suppress the manufacturing cost of the electrical junction box 100.

The same reference numerals are given to the components that are the same as those of Embodiment 1, and detailed descriptions thereof are omitted.

### Embodiment 3

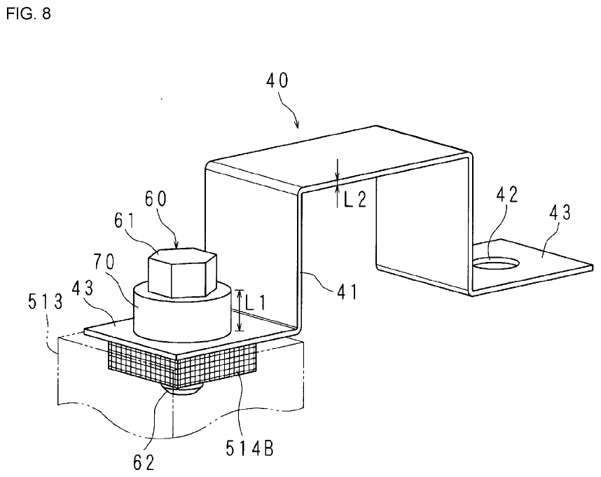

FIG. 8 is a perspective view illustrating the electrical junction box 100 according to Embodiment 3 in a state in which the busbar 40 is attached to the seat 513. In FIG. 8, for ease of description, the seat 513 is shown in dashed-two dotted lines.

In the electrical junction box 100 according to Embodiment 3, as a result of the bolt 60 being inserted into the fixation hole 42 (see in FIG. 4) in the busbar 40, and being screwed with a square nut 514B of the seat 513, the busbar 40 (flat guard 43) is fixed to the seat 513. FIG. 8 shows a case where only one of the flat guards 43 of the busbar 40 is attached to the seat 513.

Also, the washer 70 is interposed between the bolt 60 and the flat guard 43 of the busbar 40. That is to say, the washer 70 is interposed between the hexagonal retaining head 61 of the bolt 60 and the flat guard 43.

The washer 70 is tubular, and has an inner diameter that is smaller than the retaining head 61 of the bolt 60 and is larger than the outer diameter of the columnar thread portion 62. Also, the thickness L1 of the washer 70 is at least 1.5 times as large as a thickness L2 of the busbar 40. Furthermore, the washer 70 is made of the same material as that of the busbar 40.

Furthermore, in the electrical junction box 100 according to Embodiment 3, knurling is performed on the surface of the square nut 514B and the surface of the square nut 514B is uneven.

As described above, in the electrical junction box 100 according to Embodiment 3, since the washer 70 is made of the same material as that of the busbar 40, the heat generated in the busbar 40 due to current conduction rapidly propagates to and is absorbed by the washer 70. Also, since the thickness L1 of the washer 70 is at least 1.5 times as large as the thickness L2 of the busbar 40, the washer 70 can store a significant amount of heat of the busbar 40. The heat absorbed by the washer 70 is dissipated with air cooling via the surface of the washer 70.

Also, in the electrical junction box 100 according to Embodiment 3, since the surface of the square nut 514B is uneven, a large specific surface area of the square nut 514B is ensured, and the square nut 514B has a larger area that is in contact with air.

Accordingly, when part of heat absorbed by the washer 70 is dissipated with air cooling via the square nut 514B, more efficient air cooling is achieved.

With this, in the electrical junction box 100 according to Embodiment 3, it is not necessary to increase the dimension of the busbar 40 in order to endure and dissipate the heat generated due to current conduction, making it possible to suppress the dimension of the busbar 40 to the extent that press work using a progressive die is possible. This enables to achieve mass production and suppress the process cost, increasing the yield ratio. Also, no other component for increasing thermal mass is needed, and it is thus possible to reduce the number of components, and suppress the manufacturing cost of the electrical junction box 100.

The same reference numerals are given to the components that are the same as those of Embodiment 1, and detailed descriptions thereof are omitted.

### Embodiment 4

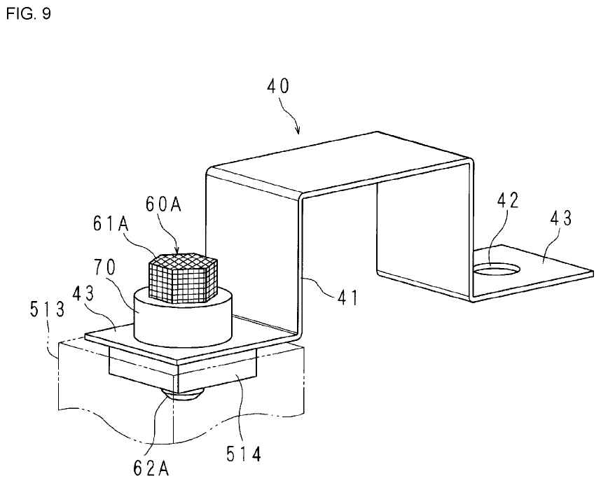

FIG. 9 is a perspective view illustrating the electrical junction box 100 according to Embodiment 4 in a state in which the busbar 40 is attached to the seat 513. In FIG. 9, for ease of description, the seat 513 is shown in dashed-two dotted lines.

In the electrical junction box 100 according to Embodiment 4, as a result of a bolt 60A being inserted into the fixation hole 42 (see in FIG. 4) in the busbar 40, and being screwed with the square nut 514 of the seat 513, the busbar 40 (flat guard 43) is fixed to the seat 513. FIG. 9 shows a case where only one of the flat guards 43 of the busbar 40 is attached to the seat 513.

Also, the washer 70 is interposed between the bolt 60A and the flat guard 43 of the busbar 40. That is to say, the washer 70 is interposed between a hexagonal retaining head 61A of the bolt 60A and the flat guard 43.

The washer 70 is tubular, and has an inner diameter that is smaller than the retaining head 61A of the bolt 60A and is larger than the outer diameter of the columnar thread portion 62A. Also, the thickness L1 of the washer 70 is at least 1.5 times as large as a thickness L2 of the busbar 40. Furthermore, the washer 70 is made of the same material as that of the busbar 40.

Furthermore, in the electrical junction box 100 according to Embodiment 4, knurling is performed on the surface of the retaining head 61A of the bolt 60A and the surface of the retaining head 61A is uneven.

As described above, in the electrical junction box 100 according to Embodiment 4, since the washer 70 is made of the same material as that of the busbar 40, the heat generated in the busbar 40 due to current conduction rapidly propagates to and is absorbed by the washer 70. Also, since the thickness L1 of the washer 70 is at least 1.5 times as large as the thickness L2 of the busbar 40, the washer 70 can store a significant amount of heat of the busbar 40. The heat absorbed by the washer 70 is dissipated with air cooling via the surface of the washer 70.

Also, in the electrical junction box 100 according to Embodiment 4, since the surface of the retaining head 61A of the bolt 60A is uneven, a large specific surface area of the retaining head 61A is ensured, and the retaining head 61A has a larger area that is in contact with air.

Accordingly, when part of heat absorbed by the washer 70 is dissipated with air cooling via the retaining head 61A, more efficient air cooling is achieved.

With this, in the electrical junction box 100 according to Embodiment 4, it is not necessary to increase the dimension of the busbar 40 in order to endure and dissipate the heat generated due to current conduction, making it possible to suppress the dimension of the busbar 40 to the extent that press work using a progressive die is possible. This enables to achieve mass production and suppress the process cost, increasing the yield ratio. Also, no other component for increasing thermal mass is needed, and it is thus possible to reduce the number of components, and suppress the manufacturing cost of the electrical junction box 100.

The same reference numerals are given to the components that are the same as those of Embodiment 1, and detailed descriptions thereof are omitted.

Although a case has been described in which the surface of the washer 70B, the surface of the retaining head 61A of the bolt 60A, or the surface of the square nut 514B is uneven, the electrical junction box 100 according to the present embodiment is not limited to this. A configuration is also possible in which all of the surface of the washer 70B, the surface of the retaining head 61A of the bolt 60A, and the surface of the square nut 514B are uneven.

The embodiments disclosed herein are examples in all respects, and should be construed as non-limiting. The scope of the present disclosure is defined by the claims, and all modifications within the meaning and scope equivalent to the claims are intended to be included.

1. An electrical junction box for vehicles that is provided with a busbar fixed using a bolt and a nut, the electrical junction box comprising:
a washer that is interposed between the bolt and the busbar, and is made of the same material as that of the busbar,
wherein the washer has an uneven surface.

2. The electrical junction box according to claim 1, wherein the washer has a thickness that is at least 1.5 times as large as a thickness of the busbar.

3. The electrical junction box according to claim 1, wherein the washer is made of copper.

4. (canceled)

5. (canceled)

6. (canceled)

7. An electrical junction box for vehicles that is provided with a busbar fixed using a bolt and a nut, the electrical junction box including,
a washer that is interposed between the bolt and the busbar, and is made of the same material as that of the busbar,
wherein the bolt has a head with an uneven surface.

8. An electrical junction box for vehicles that is provided with a busbar fixed using a bolt and a nut, the electrical junction box including,
a washer that is interposed between the bolt and the busbar, and is made of the same material as that of the busbar,
wherein the nut has an uneven outer surface.

9. The electrical junction box according to claim 7, wherein the washer has a thickness that is at least 1.5 times as large as a thickness of the busbar.

10. The electrical junction box according to claim 8, wherein the washer has a thickness that is at least 1.5 times as large as a thickness of the busbar.

11. The electrical junction box according to claim 2, wherein the washer is made of copper.

12. The electrical junction box according to claim 7, wherein the washer is made of copper.

13. The electrical junction box according to claim 8, wherein the washer is made of copper.
